(19) United States
(12) Patent Application Publication
(10) Pub. No.: US 2025/0354599 A1
(43) Pub. Date: Nov. 20, 2025

(54) SERVER, DAMPING MECHANISM AND STOP ASSEMBLY

(71) Applicant: WISTRON CORPORATION, New Taipei City (TW)

(72) Inventor: Zhong Hui MAO, New Taipei City (TW)

(73) Assignee: WISTRON CORPORATION, New Taipei City (TW)

(21) Appl. No.: 18/784,431

(22) Filed: Jul. 25, 2024

(30) Foreign Application Priority Data
May 20, 2024 (CN) 202410629757.0

(51) Int. Cl. F16F 15/04; H05K 7/14

(52) U.S. Cl. CPC F16F 15/04; H05K 7/1487; F16F 2230/0058; F16F 2232/06

(57) ABSTRACT

A server including a server casing, an electronic module and a damping mechanism is provided. The electronic module is detachably disposed in the server casing along a sliding direction. The damping mechanism includes a bracket and a stop assembly. The bracket is slidably disposed on the server casing along the sliding direction. The stop assembly is pivotally disposed on the bracket. In response to an impact force of the electronic module to the bracket being greater than a predetermined value, the stop assembly is positioned at the server casing.

### CROSS-REFERENCE TO RELATED APPLICATION

This application claims the priority and benefit of Chinese Patent Application No. 202410629757.0 filed on May 20, 2024, the disclosure of which is hereby incorporated in its entirety by reference herein.

### BACKGROUND

### Technical Field

The disclosure relates to an electronic device, a damping mechanism and a stop assembly, and particularly relates to a server, and a damping mechanism and a stop assembly included therein.

### Description of Related Art

Artificial intelligence servers usually use central processing units and acceleration chips to meet their huge computing power requirements, and the acceleration chips include logic chips such as graphics processing units (GPUs), etc. The GPUs have become a first choice for acceleration chips of artificial intelligence servers due to that they have the strongest computing power and meanwhile have deep learning and other capabilities. When a GPU module slides into a slot from the back of a server casing, a connector at the front of the GPU module is docked with a connector of a server system.

### SUMMARY

The disclosure is directed to a server, and a damping mechanism and a stop assembly.

The disclosure provides a server including a server casing, an electronic module and a damping mechanism. The electronic module is detachably disposed in the server casing along a sliding direction. The damping mechanism includes a bracket and a stop assembly. The bracket is slidably disposed on the server casing along the sliding direction. The stop assembly is pivotally disposed on the bracket. In response to an impact force of the electronic module to the bracket being greater than a predetermined value, the stop assembly is positioned on the server casing.

In an embodiment of the disclosure, the damping mechanism further includes a damping pad, and the damping pad is disposed on the bracket and is adapted to be impacted by the electronic module and transfer an impact force to the bracket.

In an embodiment of the disclosure, the stop assembly includes a positioning member and a rolling member, the positioning member is pivotally connected to the bracket, and the rolling member is movably arranged on the bracket. In response to the impact force, the rolling member drives the positioning member to rotate so that the positioning member is positioned on the server casing.

In an embodiment of the disclosure, the bracket has a leaning portion, the rolling member leans against the leaning portion, and the leaning portion is adapted to transfer the impact force to the rolling member so that the rolling member moves toward the positioning member.

In an embodiment of the disclosure, the stop assembly further includes a guide member, the guide member is disposed on the bracket and has a guide groove, and the rolling member is disposed in the guide groove and suitable for moving towards the positioning member through guidance of the guide groove.

In an embodiment of the disclosure, the guide groove has a first end and a second end opposite to each other, the second end faces the positioning member, the guide groove extends obliquely downward from the second end to the first end, and the rolling member is adapted to be located at the first end by gravity.

In an embodiment of the disclosure, the server casing has a slot, the slot has a first section and a second section connected with each other, the first section extends along the sliding direction, and the second section extends in a direction not parallel to the sliding direction, the positioning member has a column portion, the column portion is slidably installed in the slot, the column portion is adapted to move along the first section as the bracket moves along the sliding direction, and the rolling member is adapted to drive the positioning member to rotate so that the column portion moves into the second section to prevent the positioning member from moving in the sliding direction.

In an embodiment of the disclosure, the damping mechanism further includes an elastic member, the elastic member is connected between the bracket and the server casing, the bracket is adapted to resist an elastic force of the elastic member to move in the sliding direction, and is adapted to be restored by the elastic force of the elastic member.

In an embodiment of the disclosure, the positioning member has an accommodating recess, and the accommodating recess is adapted to accommodate the rolling member.

The disclosure provides a damping mechanism including a main body, a bracket and a stop assembly. The bracket is slidably disposed on the main body along a sliding direction. The stop assembly is pivotally disposed on the bracket, wherein in response to an impact force applied to the bracket being greater than a predetermined value, the stop assembly is positioned on the main body.

In an embodiment of the disclosure, the damping mechanism further includes a damping pad, wherein the damping pad is disposed on the bracket and is adapted to be impacted and transfer the impact force to the bracket.

In an embodiment of the disclosure, the stop assembly includes a positioning member and a rolling member, the positioning member is pivotally connected to the bracket, and the rolling member is movably arranged on the bracket. In response to the impact force, the rolling member drives the positioning member to rotate so that the positioning member is positioned on the main body.

In an embodiment of the disclosure, the bracket has a leaning portion, the rolling member leans against the leaning portion, and the leaning portion is adapted to transfer the impact force to the rolling member so that the rolling member moves toward the positioning member.

In an embodiment of the disclosure, the stop assembly further includes a guide member, the guide member is disposed on the bracket and has a guide groove, and the rolling member is disposed in the guide groove and suitable for moving towards the positioning member through guidance of the guide groove.

In an embodiment of the disclosure, the guide groove has a first end and a second end opposite to each other, the second end faces the positioning member, the guide groove extends obliquely downward from the second end to the first end, and the rolling member is adapted to be located at the first end by gravity.

In an embodiment of the disclosure, the main body has a slot, the slot has a first section and a second section connected with each other, the first section extends along the sliding direction, and the second section extends in a direction not parallel to the sliding direction, the positioning member has a column portion, the column portion is slidably installed in the slot, the column portion is adapted to move along the first section as the bracket moves along the sliding direction, and the rolling member is adapted to drive the positioning member to rotate so that the column portion moves into the second section to prevent the positioning member from moving in the sliding direction.

In an embodiment of the disclosure, the damping mechanism further includes an elastic member, wherein the elastic member is connected between the bracket and the main body, the bracket is adapted to resist an elastic force of the elastic member to move in the sliding direction, and is adapted to be restored by the elastic force of the elastic member.

In an embodiment of the disclosure, the positioning member has an accommodating recess, and the accommodating recess is adapted to accommodate the rolling member.

The disclosure provides a stop assembly including a body, a positioning member and a rolling member. The positioning member is pivotally connected to the body. The rolling member is movably arranged on the body, wherein in response to an impact force applied to the body being greater than a predetermined value, the positioning member is positioned through the rolling member.

In an embodiment of the disclosure, the stop assembly further includes a guide member, wherein the guide member is disposed on the body and has a guide groove, and the rolling member is disposed in the guide groove and suitable for moving towards the positioning member through guidance of the guide groove.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a three-dimensional view of a server according to an embodiment of the disclosure.

FIG. 2 is a three-dimensional view of an electronic module of FIG. 1.

FIG. 3A to FIG. 3C illustrate an installation process of the electronic module of FIG. 1.

FIG. 4A to FIG. 4C are respectively partial side views of the server of FIG. 3A to 3C.

FIG. 5 is an exploded view of a partial structure of the server of FIG. 1.

FIG. 6 is a three-dimensional view of a bracket of FIG. 5.

FIG. 7 is a partial three-dimensional of a server casing of FIG. 5.

FIG. 8 is a three-dimensional view of a positioning member of FIG. 5.

FIG. 9 is a three-dimensional view of a guide member of FIG. 5.

### DETAILED DESCRIPTION

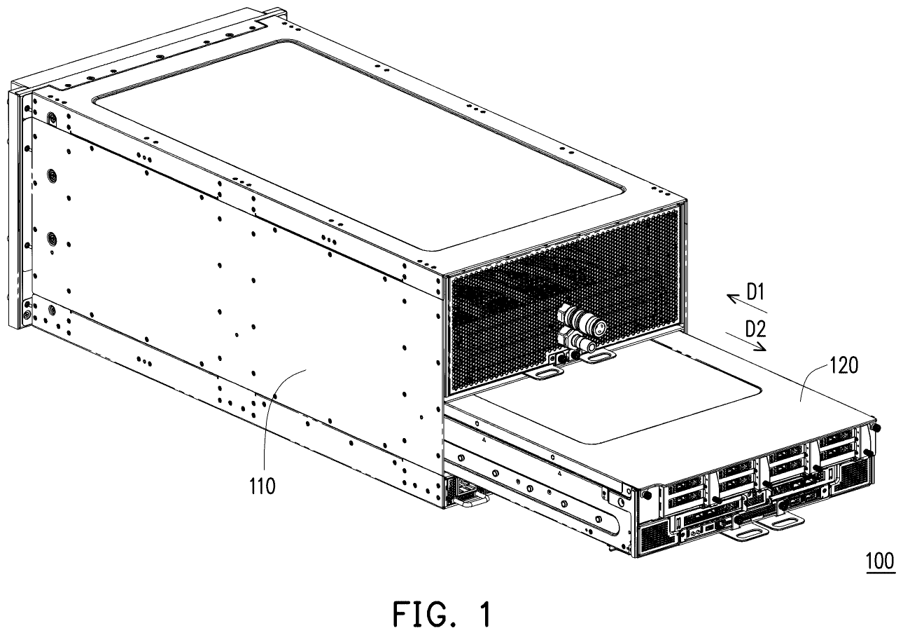

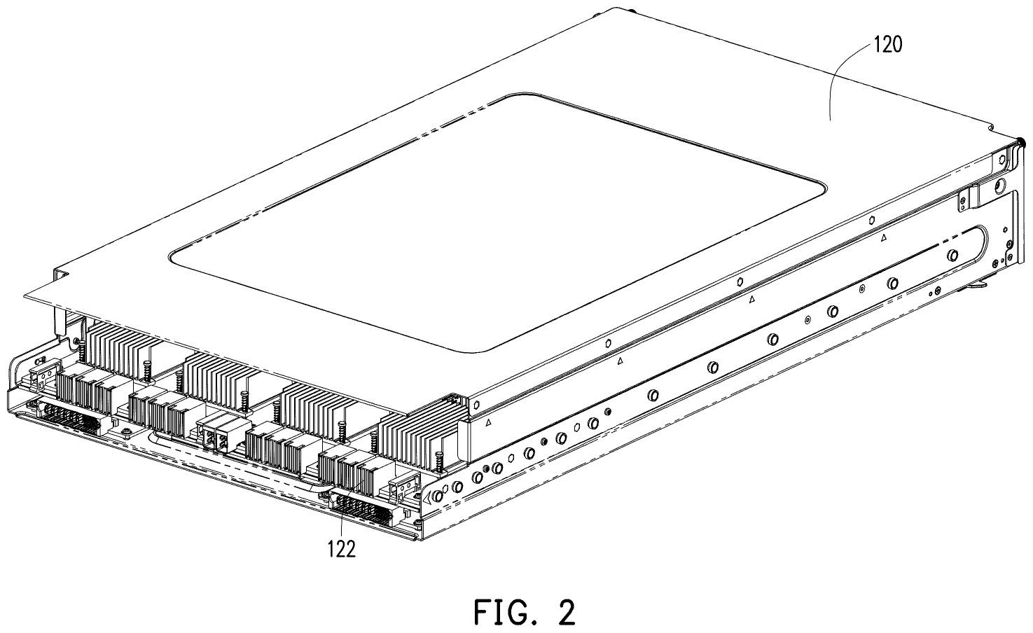

FIG. 1 is a three-dimensional view of a server according to an embodiment of the disclosure. FIG. 2 is a three-dimensional view of an electronic module of FIG. 1. Referring to FIG. 1 and FIG. 2, a server 100 of the embodiment includes a server casing 110 and an electronic module 120. The electronic module 120 is, for example, a graphics processing unit (GPU) module or other types of logic chip modules, which is detachably arranged in the server casing 110 along a sliding direction D1. A connector 122 of the electronic module 120 is used to be docked with a connector of a server system in the server casing 110.

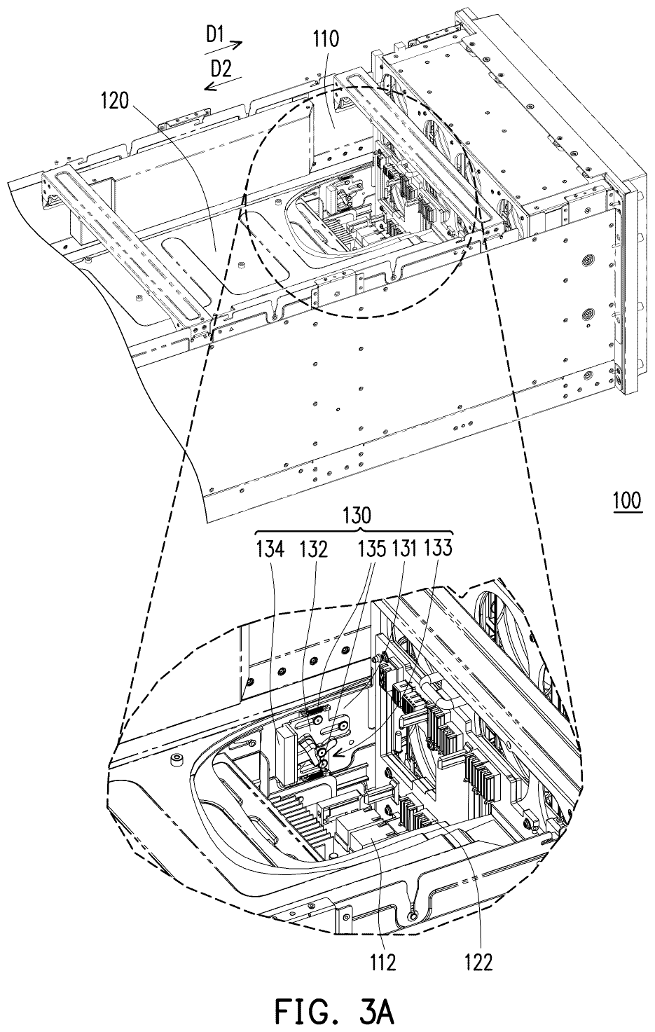

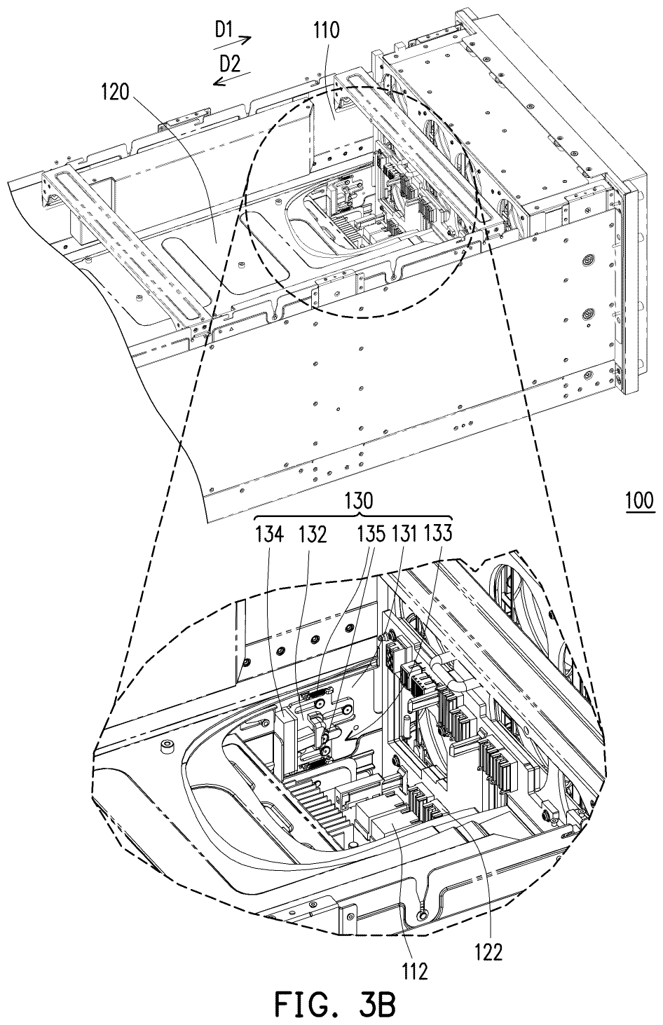

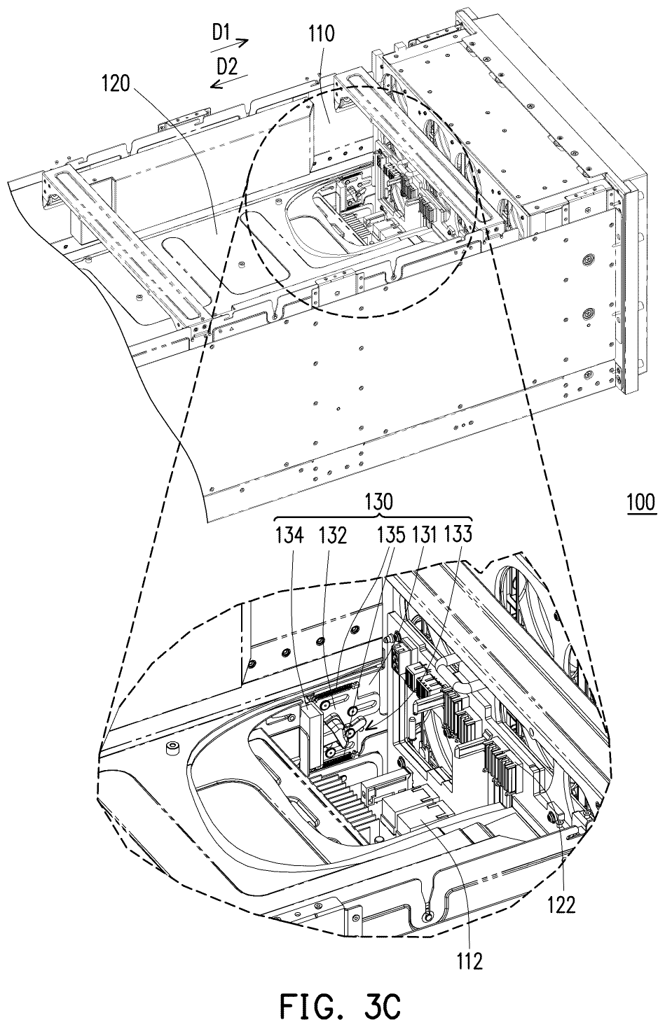

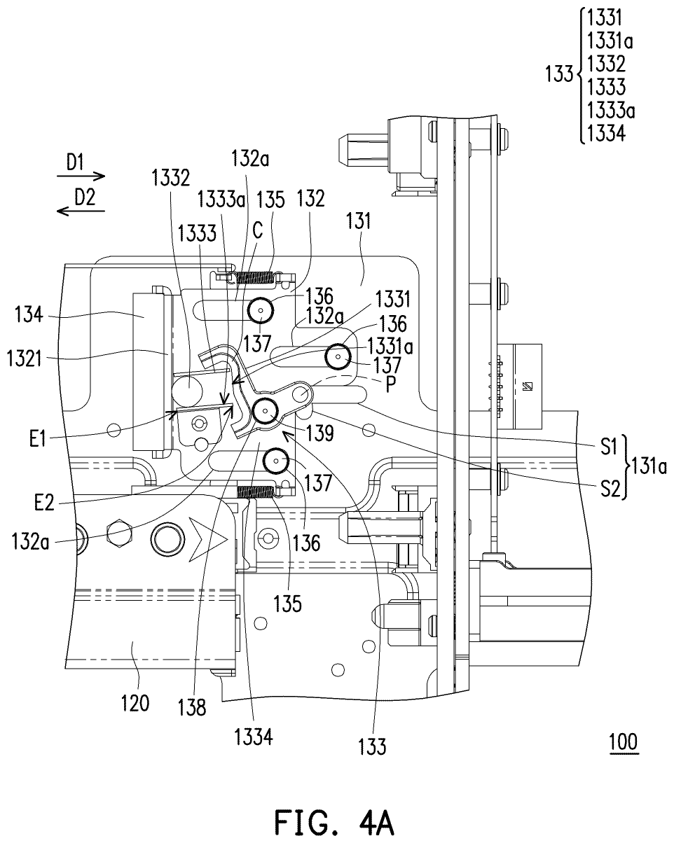

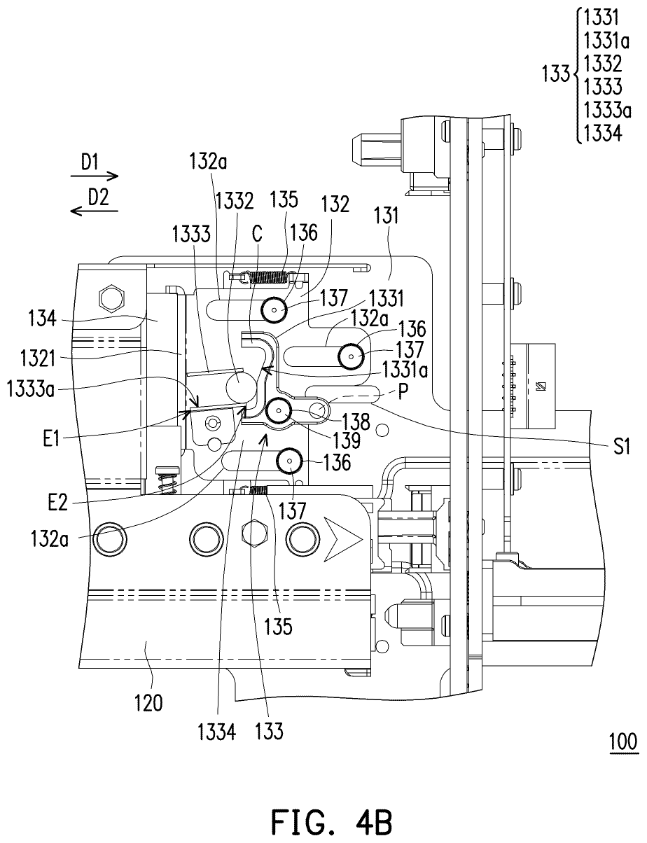

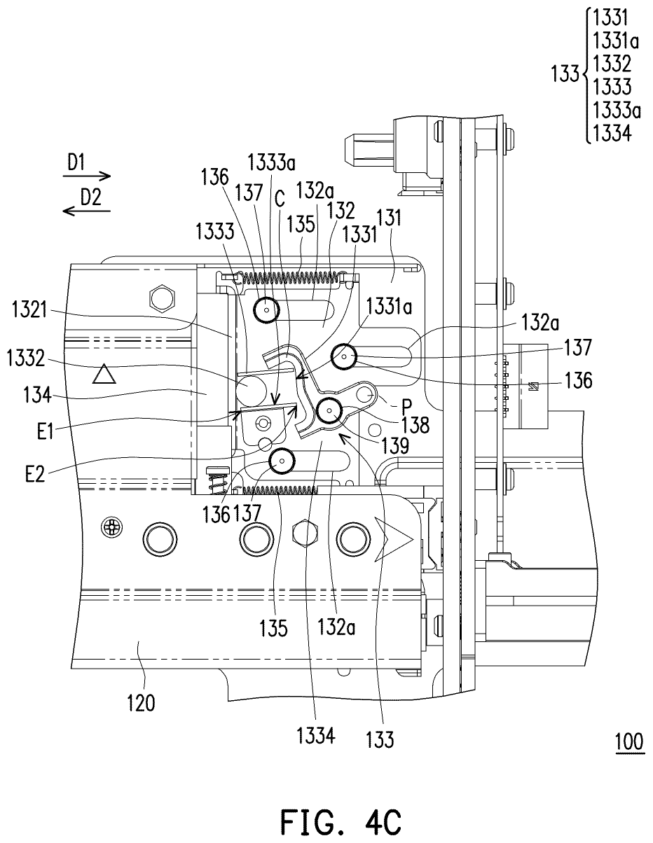

FIG. 3A to FIG. 3C illustrate an installation process of the electronic module of FIG. 1. FIG. 4A to FIG. 4C are respectively partial side views of the server of FIG. 3A to 3C. Referring to FIG. 3A to FIG. 4C, the server 100 of the embodiment further includes a damping mechanism 130. The damping mechanism 130 includes a main body 131, a bracket 132, a stop assembly 133 and a damping pad 134. The main body 131 is a part of the server casing 110, and the bracket 132 is slidably disposed on the main body 131 (i.e., a part of the server casing 110) along the sliding direction D1. The stop assembly 133 is pivotally arranged on the bracket 132. The damping pad 134 is disposed on the bracket 132 and is suitable for being hit by the electronic module 120 and transfer an impact force to the bracket 132. In response to the impact force of the electronic module 120 on the bracket 132 being greater than a predetermined value, the stop assembly 133 is actuated from a state shown in FIG. 3A and FIG. 4A to a state shown in FIG. 3B and FIG. 4B and is positioned on the server casing 110, so as to prevent the bracket 132 from moving along the sliding direction D1, and the damping pad 134 is compressed between the bracket 132 and the electronic module 120 during this process to provide a damping effect.

As mentioned above, in the server 100 of the disclosure, the damping mechanism 130 is provided on the server casing 110. When the user installs the electronic module 120 along the sliding direction D1 with an excessive force, the impact force of the electronic module 120 on the bracket 132 of the damping mechanism 130 that exceeds a predetermined value may trigger the stop assembly 133 of the damping mechanism 130 to operate, and the stop assembly 133 may prevent the bracket 132 from moving in the sliding direction D1, so that the electronic module 120 is stopped by the bracket 132. Accordingly, the connector 122 of the electronic module 120 may be prevented from directly hitting a connector 112 of the server system at high speed under excessive force exerted by the user, thereby preventing the connector 122 of the electronic module 120 and the connector 112 of the server system from colliding with each other to cause damage. The disclosure does not limit the predetermined value, which may be a critical value or a lower value of an initial impact force sufficient to cause impact damage to the connectors 112 and 122.

In the embodiment, the damping mechanism 130 is disposed on a single side of the server casing 110 as shown in FIG. 3A, but the disclosure is not limited thereto. In other embodiments, two damping mechanisms 130 may be symmetrically disposed on two opposite sides of the server casing 110 to balance forces.

The damping mechanism 130 of the embodiment further includes an elastic member 135. The elastic member 135 is, for example, a spring and is connected between the bracket 132 and the main body 131 (i.e., a part of the server casing 110). After the electronic module 120 is stopped by the damping pad 134 as shown in FIG. 3B and FIG. 4B and the stop assembly 133 is reset, the user may again apply a force on the electronic module 120 along the sliding direction D1. At this time, the electronic module 120 and the bracket 132 pushed by the electronic module 120 resist the elastic force of the elastic member 135 and move along the sliding direction D1 to the state shown in FIG. 3C and FIG. 4C, and the connector 122 of the electronic module 120 is docked with the connector 112 of the server system to complete the installation of electronic module 120. When the user disassembles the electronic module 120 along a sliding direction D2 opposite to the sliding direction D1, the bracket 132 is reset to the state shown in FIG. 3A and FIG. 4A by the elastic force of the elastic member 135.

The detailed configuration and function of the damping mechanism 130 of the embodiment will be described in detail below.

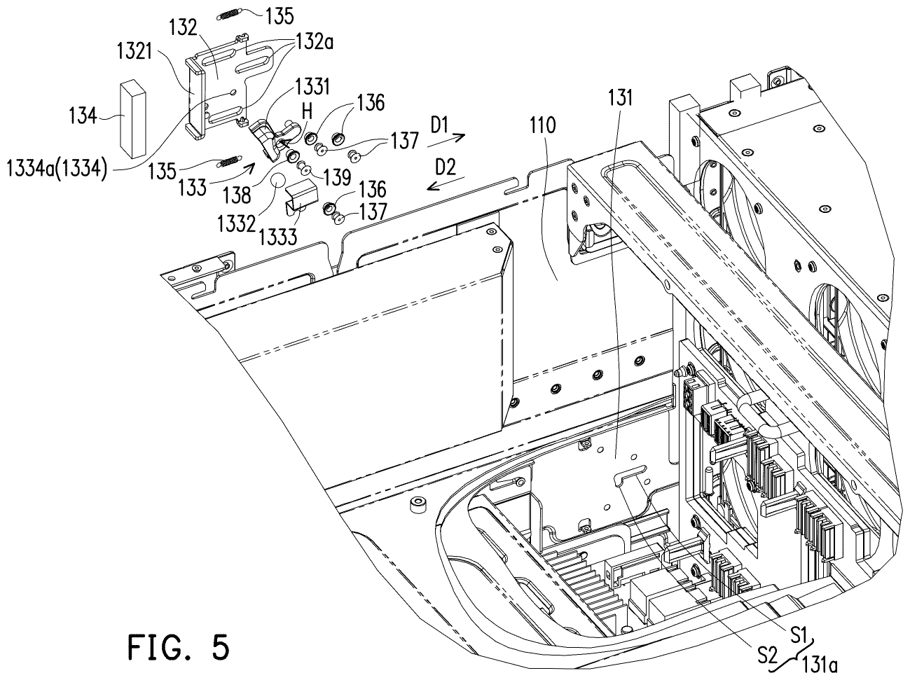

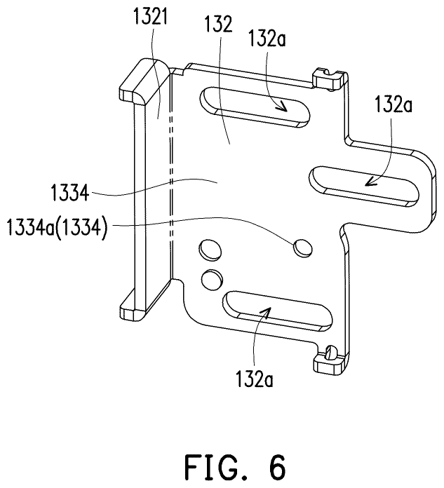

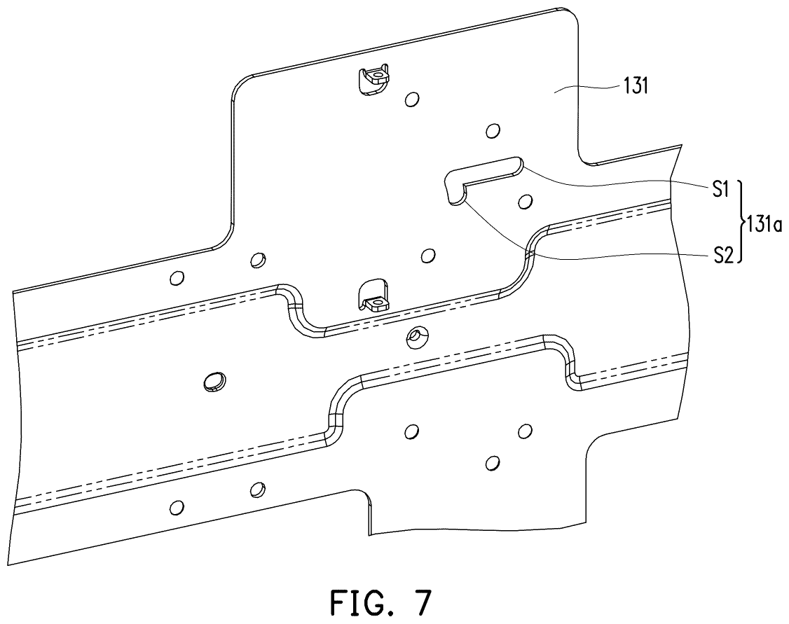

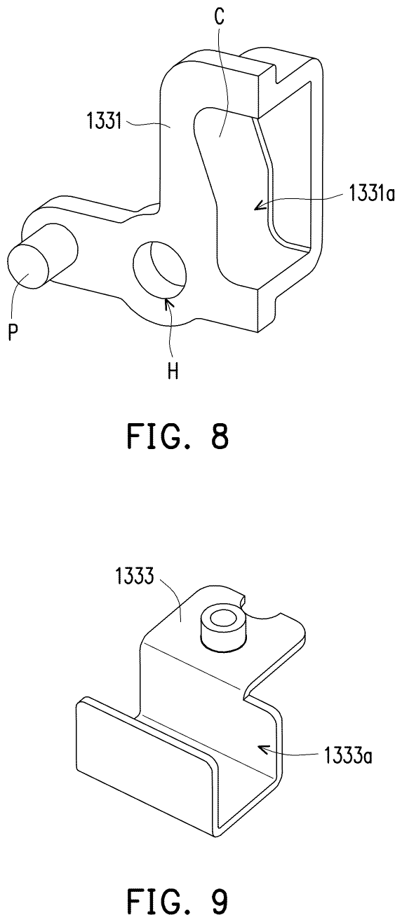

FIG. 5 is an exploded view of a partial structure of the server of FIG. 1. FIG. 6 is a three-dimensional view of a bracket of FIG. 5. FIG. 7 is a partial three-dimensional of a server casing of FIG. 5. FIG. 8 is a three-dimensional view of a positioning member of FIG. 5. FIG. 9 is a three-dimensional view of a guide member of FIG. 5. Referring to FIG. 5 and FIG. 6, the bracket 132 of the embodiment has a plurality of slide grooves 132a and is slidably disposed on the main body 131 (i.e., a part of the server casing 110) along the sliding direction D1 through the slide grooves 132a.

In detail, in the embodiment, a plurality of columns 136 (shown in FIG. 4A to FIG. 4C and FIG. 5) respectively pass through the plurality of slide grooves 132a of the bracket 132, and a plurality of locking parts 137 (shown in FIG. 4A to FIG. 4C and FIG. 5) are used to respectively fix the plurality of columns 136 to the server casing 110 so that the bracket 132 is slidably disposed on the main body 131 as described above.

In addition, the stop assembly 133 of the embodiment includes a positioning member 1331, a rolling member 1332 and a body 1334 as shown in FIG. 4A and FIG. 5. The body 1334 is a part of the bracket 132. The positioning member 1331 is pivotally connected to the body 1334 (i.e., a part of the bracket 132) through a pivot hole H (marked in FIG. 8) thereof. The main body 131 (i.e., a part of the server casing 110) has a slot 131a as shown in FIG. 4A, FIG. 5 and FIG. 7. The slot 131a has a first section S1 and a second section S2 connected with each other, the first section S1 extends along the sliding direction D1, and the second section S2 extends along a direction that is not parallel to the sliding direction D1. The positioning member 1331 has a column portion P as shown in FIG. 4A and FIG. 8, and the column portion P is slidably installed in the slot 131a. In a natural state, the positioning member 1331 is in an inclined state as shown in FIG. 4A by gravity, and the column portion P is located in the first section S1.

The bracket 132 has a leaning portion 1321, the damping pad 134 is provided on one side of the leaning portion 1321. The rolling member 1332 is, for example, a ball, the rolling member 1332 is movably arranged on the bracket 132 and leans against another side of the leaning portion 1321. In other embodiments, the rolling member 1332 may be a cylinder or other appropriate shapes, which is not limited by the disclosure. The stop assembly 133 further includes a guide member 1333, which is disposed on the bracket 132 and has a guide groove 1333a. The guide groove 1333a has a first end E1 and a second end E2 opposite to each other, the second end E2 faces the positioning member 1331, the guide groove 1333a extends obliquely downward from the second end E2 to the first end E1, and the rolling member 1332 is disposed in the guide groove 1333a and is located at the first end E1 by gravity.

When the force exerted by the user on the electronic module 120 along the sliding direction D1 is not too large, the impact force of the electronic module 120 applied on the damping mechanism 130 is not enough to move the rolling member 1332 toward the positioning member 1331. Therefore, the positioning member 1331 does not rotate and the column portion P thereof is maintained at the position shown in FIG. 4A, so that the column portion P may move along the first section S1 as the bracket 132 moves along the sliding direction D1, and the electronic module 120 may smoothly push the bracket 132 to move along the sliding direction D1 to complete the installation.

On the contrary, when the force exerted by the user on the electronic module 120 along the sliding direction D1 is too large, the positioning member 1331 may be positioned by the operation of the rolling member 1332. To be specific, the leaning portion 1321 transfers a sufficiently large impact force (i.e., the aforementioned impact force greater than the predetermined value) to the rolling member 1332, and the rolling member 1332 moves toward the positioning member 1331 through guidance of the guide groove 1333a in response to the impact force as shown in FIG. 4B, which drives the positioning member 1331 to rotate and moves the column portion P into the second section S2 to prevent the positioning member 1331 from moving along the sliding direction D1, thereby positioning the positioning member 1331 on the main body 131 (i.e., a part of the server casing 110). An actual value of the predetermined value may be adjusted, for example, by changing a weight of the rolling member 1332, and the greater the weight of the rolling member 1332 is, the greater the corresponding predetermined value is. The specific calculation and/or simulation method of the predetermined value may be implemented based on the known knowledge in the art, and detail thereof is not repeated.

In detail, the embodiment is to pass a column 138 (shown in FIG. 4A to FIG. 4C and FIG. 5) through the pivot hole H of the positioning member 1331, and use a locking member 139 (shown in FIG. 4A to FIG. 4C and FIG. 5) to fix the column 138 to a mounting hole 1334a of the body 1334, so that the positioning member 1331 is pivotally connected to the body 1334 as mentioned above, and may then rotate between a non-positioned state of FIG. 4A and a positioned state of FIG. 4B as mentioned above.

After the electronic module 120 is stopped by the damping pad 134 as shown in FIG. 4B, the rolling member 1332 moves to the first end E1 of the guide groove 1333a by gravity, the positioning member 1331 is also reset by gravity so that the column portion P moves upward and away from the second section S2, and the positioning member 1331 may also be provided with an elastic member such as a torsion spring and is reset by its elastic force. At this time, the user may again apply a force on the electronic module 120 along the sliding direction D1, and the electronic module 120 and the bracket 132 pushed by the electronic module 120 resist the elastic force of the elastic member 135 and move along the sliding direction D1 to the state shown in FIG. 4C to complete the installation of the electronic module 120. During the process of the electronic module 120 and the bracket 132 moving along the sliding direction D1 from the state of FIG. 4B to the state of FIG. 4C, the column portion P moves along the first section S1 as the bracket 132 moves along the sliding direction D1.

In the embodiment, the positioning member 1331 has an accommodating recess 1331a as shown in FIG. 8. The accommodating recess 1331a is used to accommodate the rolling member 1332 in the state shown in FIG. 4B to prevent the rolling member 1332 from falling off. In addition, a recessed area C is further formed in the accommodating recess 1331a to avoid the guide member 1333 as shown in FIG. 4A, so that the positioning member 1331 may tilt to the state in FIG. 4A in a natural state.

In summary, in the server of the disclosure, the damping mechanism is provided on the server casing. When the user applies an excessive force to install the electronic module in the sliding direction, the impact force of the electronic module on the bracket of the damping mechanism that exceeds a predetermined value may trigger the stop assembly of the damping mechanism to operate, and the stop assembly may prevent the bracket from moving in the sliding direction, so that the electronic module is stopped by the bracket. Accordingly, the connector of the electronic module may be prevented from directly hitting the connector of the server system at a high speed under excessive force exerted by the user, thereby preventing the connector of the electronic module and the connector of the server system from colliding with each other to cause damage.

What is claimed is:

1. A server, comprising:
a server casing;
an electronic module, detachably disposed in the server casing along a sliding direction; and
a damping mechanism, including:
a bracket, slidably disposed on the server casing along the sliding direction; and
a stop assembly, pivotally disposed on the bracket, and adapted to, in response to an impact force of the electronic module to the bracket being greater than a predetermined value, be positioned on the server casing.

2. The server as claimed in claim 1, wherein the damping mechanism further comprises a damping pad disposed on the bracket and adapted to be impacted by the electronic module and the impact force is transferred from the electronic module to the bracket via the damping pad.

3. The server as claimed in claim 1, wherein the stop assembly comprises:
a positioning member, pivotally connected to the bracket; and
a rolling member, movably arranged on the bracket, and adapted to in response to the impact force, the positioning member being driven to rotate by the rolling member, and the positioning member is positioned on the server casing.

4. The server as claimed in claim 3, wherein the bracket has a leaning portion, leaned against by the rolling member, and the impact force is transferred to the rolling member via the leaning portion, and the rolling member is moved toward the positioning member by the impact force.

5. The server as claimed in claim 3, wherein the stop assembly further comprises a guide member, disposed on the bracket and having a guide groove, and the rolling member is disposed in the guide groove and is moved towards the positioning member through guidance of the guide groove.

6. The server as claimed in claim 5, wherein the guide groove includes a first end and a second end opposite to each other, the positioning member is faced by the second end, the guide groove is extended obliquely downward from the second end to the first end, and the rolling member is located at the first end by gravity.

7. The server as claimed in claim 3, wherein the server casing includes a slot having a first section and a second section connected with each other, the first section is extended along the sliding direction, and the second section is extended in a direction not parallel to the sliding direction, the positioning member has a column portion slidably installed in the slot and moved along the first section as the bracket is moved along the sliding direction, and the positioning member is rotated by the rolling member being driven, and the column portion is moved into the second section, the positioning member is prevented from being moved in the sliding direction.

8. The server as claimed in claim 3, wherein the damping mechanism further comprises an elastic member connected between the bracket and the server casing, and an elastic force of the elastic member is resisted by the bracket moved in the sliding direction, and the bracket is restored by the elastic force of the elastic member.

9. The server as claimed in claim 3, wherein the positioning member has an accommodating recess, and the rolling member is accommodated by the accommodating recess.

10. A damping mechanism, including:
a main body;
a bracket, slidably disposed on the main body along a sliding direction; and
a stop assembly, pivotally disposed on the bracket, and adapted to, in response to an impact force applied to the bracket being greater than a predetermined value, be positioned on the main body.

11. The damping mechanism as claimed in claim 10, further comprising a damping pad, disposed on the bracket and is adapted to be impacted and the impact force is transferred from the electronic module to the bracket via the damping pad.

12. The damping mechanism as claimed in claim 10, wherein the stop assembly comprises:
a positioning member, pivotally connected to the bracket; and
a rolling member, movably arranged on the bracket, and adapted to, in response to the impact force, the positioning member being driven to rotate by the rolling member, and the positioning member is positioned on the main body.

13. The damping mechanism as claimed in claim 12, wherein the bracket includes a leaning portion leaned against by the rolling member, and the leaning portion is adapted to transfer the impact force to the rolling member so that the rolling member moves toward the positioning member.

14. The damping mechanism as claimed in claim 12, wherein the stop assembly further comprises a guide member, disposed on the bracket and having a guide groove, and the rolling member is disposed in the guide groove and is moved towards the positioning member through guidance of the guide groove.

15. The damping mechanism as claimed in claim 14, wherein the guide groove includes a first end and a second end opposite to each other, the second end the positioning member is faced by the second end, the guide groove is extended obliquely downward from the second end to the first end, and the rolling member is located at the first end by gravity.

16. The damping mechanism as claimed in claim 12, wherein the main body includes a slot having a first section and a second section connected with each other, the first section is extended along the sliding direction, and the second section is extended in a direction not parallel to the sliding direction, the positioning member has a column portion slidably installed in the slot and moved along the first section as the bracket is moved along the sliding direction, and the positioning member is rotated by the rolling member being driven, and the column portion is moved into the second section, the positioning member is prevented from being moved in the sliding direction.

17. The damping mechanism as claimed in claim 12, further comprising an elastic member connected between the bracket and the main body, and an elastic force of the elastic member is resisted by the bracket moved in the sliding direction, and the bracket is restored by the elastic force of the elastic member.

18. The damping mechanism as claimed in claim 12, wherein the positioning member includes an accommodating recess, and the rolling member is accommodated by the accommodating recess.

19. A stop assembly, comprising:
a body;
a positioning member, pivotally connected to the body; and
a rolling member, movably arranged on the body, and adapted to in response to an impact force applied to the body being greater than a predetermined value, be positioned through the rolling member.

20. The stop assembly as claimed in claim 19, further comprising a guide member disposed on the body and having a guide groove, and the rolling member is disposed in the guide groove and is moved towards the positioning member through guidance of the guide groove.
